(19) United States
(12) Patent Application Publication
(10) Pub. No.: US 2025/0008650 A1
(43) Pub. Date: Jan. 2, 2025

(54) CONTACT HEIGHT ADJUSTMENT STRUCTURE OF FLEXIBLE CIRCUIT BOARD

(71) Applicant: ADVANCED FLEXIBLE CIRCUITS CO., LTD., TAOYUAN COUNTY (TW)

(72) Inventors: CLINTON LIN, NEW TAIPEI CITY (TW); CHIH-HENG CHUO, TAOYUAN COUNTY (TW); KUO-FU SU, TAOYUAN COUNTY (TW)

(21) Appl. No.: 18/731,560

(22) Filed: Jun. 3, 2024

(30) Foreign Application Priority Data
Jun. 29, 2023 (TW) 112124212

(51) Int. Cl. H05K 1/11; H05K 1/02

(52) U.S. Cl. CPC H05K 1/111; H05K 1/0277; H05K 2201/09372

(57) ABSTRACT

A contact height adjustment structure for a flexible circuit board is provided for making a plurality of conductive zones on a first surface of the flexible circuit board in tight contact engagement with corresponding contact points of a circuit device. The flexible circuit board is provided, on a second surface opposite to the first surface, with a plurality of height adjustment pads that are arranged at intervals and correspond, in a one-to-one manner, to the plurality of conductive zones. The plurality of height adjustment pads provide the plurality of conductive zones with a pushing force toward the corresponding contact points of the circuit device, so as to adjust a contact height of the conductive zones and to achieve an effect of setting the conductive zones in tight contact engagement with the corresponding contact points.

### BACKGROUND OF THE INVENTION

### 1. Field of the Invention

The present invention relates to a contact structure of a flexible circuit board, and more particularly to a contact height adjustment structure of a flexible circuit board.

### 2. The Related Arts

Flexible circuit boards are characterized by flexibility, light weight, and thinness, and are thus widely used in connecting flat cables or connecting circuit boards. Flexible circuit boards are also applicable to contact connection of contact points of flexible circuit boards or rigid circuit boards.

Connection of a flexible circuit board with contact points of a circuit board, a flexible circuit board, a rigid circuit board, or a connector or a receptacle often adopts an arrangement of contacting with contact points to fulfill connection of electrical signals.

However, due to the flexibility of the flexible circuit board, as well as problems concerning miniaturized contact pad structures laid on the flexible circuit board and the small distance between adjacent contact pads, it is common to encounter troubles with respect to poor contact with the contact points. Further, in the fabrication of the contact pads of the flexible circuit boards, there are dimensional deviations (such as height deviation, outer contour deviation, and width deviation), resulting in stretching of stress between adjacent contact pads, and this in turn causes problems with respect to differential contact pressure, differential contact resistance, and contact position shifting between the contact pads and corresponding contact points.

### SUMMARY OF THE INVENTION

In view of the above, an objective of the present invention is to provide a contact height adjustment structure of a flexible circuit board, which makes conductive zones of a flexible circuit board in tight contact engagement with corresponding contact points of a circuit device.

The technical solution that the present invention adopts to achieve the above objective is that a flexible circuit board is provided, on a second surface that is opposite to a first surface, with a plurality of height adjustment pads that are arranged at intervals and correspond, in a one-to-one manner, to a plurality of conductive zones. The plurality of height adjustment pads provide the plurality of conductive zones with a pushing force toward corresponding contact points of a circuit device, so as to adjust a contact height of the conductive zones and to achieve an effect of situating the conductive zones in tight contact engagement with the corresponding contact points.

Preferably, each conductive zone of the plurality of conductive zones comprises one of a laid conductive line, a contact pad, and a conductive bump.

Preferably, each height adjustment pad of the plurality of height adjustment pads comprises a plate structure or a dome-shaped conductive bump having a predetermined height.

Preferably, the height adjustment pads are made of one of an insulation material, a metallic material or composite materials made from the insulation material and the metallic material.

Preferably, the conductive zones are arranged, at intervals, on the first surface of the flexible circuit board in an aligned fashion.

Preferably, the plurality of conductive zones are arranged, at intervals, on the first surface of the flexible circuit board and include a first row of contact pads and at least one second row of contact pads that are respectively arranged at a front side and a rear side and are respectively shifted leftward and rightward.

Preferably, the plurality of conductive zones are arranged, at intervals, in the form of a matrix on the first surface of the flexible circuit board and are located at a front end position of the flexible circuit board.

Preferably, the plurality of conductive zones are arranged, at intervals, in the form of a matrix on the first surface of the flexible circuit board and are located at a middle section position of the flexible circuit board.

Preferably, the corresponding circuit device comprises one of a circuit board and a receptacle.

With respect to the efficacy, the flexible circuit board of the present invention is provided, on a second surface that is opposite to a first surface on which conductive zones are arranged, with a plurality of height adjustment pads that arranged at intervals and correspond, in a one-to-one manner, to the conductive zones, and the plurality of height adjustment pads provide the plurality of conductive zones with a pushing force toward corresponding contact points of a circuit device, so as to adjust a contact height of the conductive zones and to achieve an effect of setting the conductive zones in tight contact engagement with the corresponding contact points.

Further, in the design of the present invention, the conductive zones are each provided with an independent contact pressing force acting on a corresponding contact point by a corresponding one of the height adjustment pads, and there is no mutual interference therebetween, so as to alleviate the problem of the prior art in which stress stretching may be induced between adjacent contact pads resulting from height deviation, outer contour deviation, and width deviation between the adjacent contact pads, and therefore, excellent and uniform contact pressing forces may be achieved between the contact pads and the corresponding contact points.

In the following, a specific way of implementing the present invention will be described with reference to the embodiments and the attached drawings.

### BRIEF DESCRIPTION OF THE DRAWINGS

FIG. 1 is a perspective view of a first embodiment of the present invention;

FIG. 2 is a cross-sectional view taken along line A-A of FIG. 1;

FIG. 3 is a cross-sectional view taken along line B-B of FIG. 1;

FIG. 4 shows an example of application in which the first embodiment of the present invention corresponds to and contacts with a circuit board;

FIG. 5 shows an example of application in which the first embodiment of the present invention corresponds to and contacts with a receptacle;

FIG. 6 is a cross-sectional view showing height adjustment pads according to a second embodiment of the present invention being in the form of dome-shaped conductive bump;

FIG. 7 shows an example of application in which the second embodiment of the present invention corresponds to and contacts with a circuit board;

FIG. 8 shows an example of application in which the second embodiment of the present invention corresponds to and contacts with a receptacle;

FIG. 9 is a perspective view showing conductive zones of a third embodiment of the present invention being made as contact pads that are lined up in an aligned fashion;

FIG. 10 is a perspective view showing conductive zones of a fourth embodiment of the present invention being made as contact pads arranged at front and rear sides;

FIG. 11 is a perspective view showing a conductive zone of a fifth embodiment of the present invention including contact pads arranged in a matrix form and located at a front end position of a flexible circuit board;

FIG. 12 is a perspective view showing conductive zones of a sixth embodiment of the present invention are made as contact pads arranged in a matrix form and located at a middle section of a flexible circuit board; and

FIG. 13 is a perspective view showing conductive zones of a seventh embodiment of the present invention arranged in a matrix form.

### DETAILED DESCRIPTION OF THE PREFERRED EMBODIMENTS

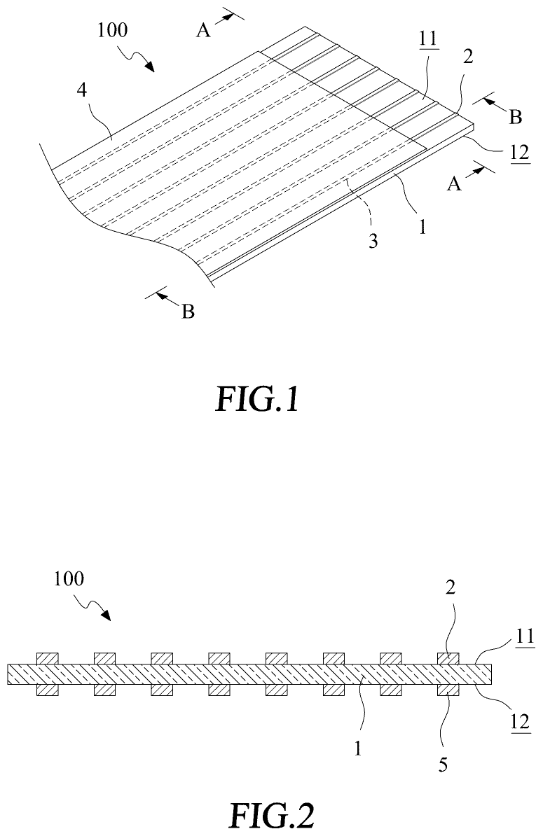

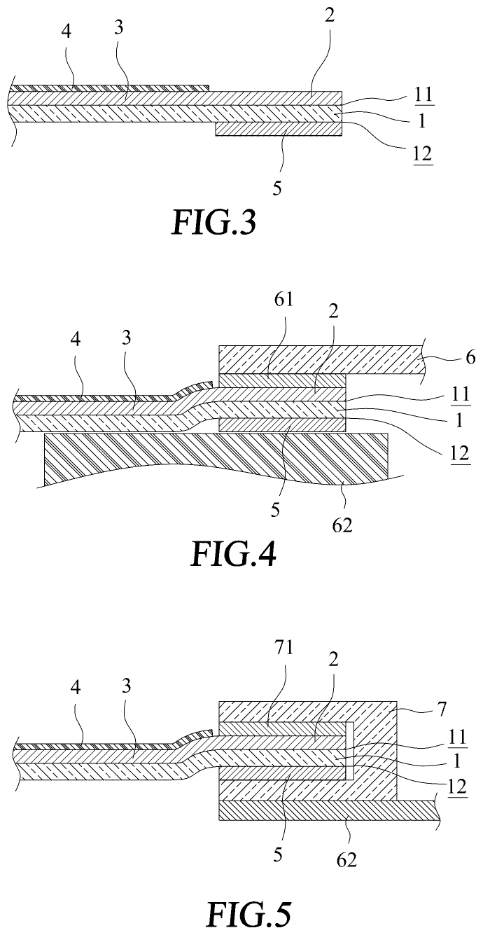

Referring jointly to FIGS. 1-3, FIG. 1 is a perspective view showing a first embodiment of the present invention; FIG. 2 is a cross-sectional view taken along line A-A of FIG. 1; and FIG. 3 is a cross-sectional view taken along line B-B of FIG. 1. As shown in the drawings, a flexible circuit board 100 comprises a substrate 1 having a first surface 11 on which a plurality of conductive zones 2 are laid. The conductive zones 2 are spaced from each other by a spacing distance and are each connected to an extended conductive line 3. The first surface 11 of the substrate 1 is covered with a protection layer 4, while the plurality of conductive zones 2 are exposed, so that when an end portion of the flexible circuit board 100 is connected to a corresponding circuit device, the conductive zones 2 can be brought into contact engagement with corresponding contact points of the circuit device to fulfill the purpose of circuit connection. The corresponding circuit device can be one of a circuit board and a receptacle.

In the instant embodiment, each conductive zone 2 of the plurality of conductive zones 2 is made in the form of a laid conductive line, meaning the conductive zones 2 is a laid conductive line extended from the conductive line 3, and the conductive zones 2 are arranged at intervals, in an aligned manner, on a front end portion of the flexible circuit board 100.

In the present invention, on a second surface 12 of the substrate 1 of the flexible circuit board that is opposite to the first surface 11, a plurality of height adjustment pads 5 are arranged at intervals and correspond, in a one-to-one manner, to the plurality of conductive zones 2. In the instant embodiment, each of the height adjustment pads 5 is a plate structure having a predetermined height and is made of one of an insulation material and a metallic material.

Referring to FIG. 4, which shows an example of application in which the first embodiment of the present invention is set to correspond to and contact with a circuit board, when the flexible circuit board 100 is combined, at an end portion, with a circuit board 6 (such as a flexible circuit board, a rigid circuit board, or a rigid-flex circuit board), each of the conductive zones 2 is put into contact engagement with a corresponding contact point 61 of the circuit board 6. Further, the height adjustment pads 5 make a thickness of the flexible circuit board 100 corresponding to a height of spacing between the circuit board 6 and a horizontal member 62 (such as a circuit board, a device bottom board, or a carrying board), and the height adjustment pads 5 provide the conductive zones 2 with a pushing force toward the corresponding contact points 61 of the circuit board 6, so as to adjust a contact height of the conductive zones 2 and to achieve an effect of situating the conductive zones 2 and the corresponding contact points 61 in tight contact engagement with each other.

Referring to FIG. 5, which shows an example of application in which the first embodiment of the present invention is set to correspond to and contact with a receptacle, when the flexible circuit board 100 is combined, at an end portion, with a receptacle 7, each of the conductive zones 2 is put into contact engagement with a corresponding contact point 71 of the receptacle 7, and the height adjustment pads 5 of the second surface 11 of the substrate 1 makes a thickness of the flexible circuit board 100 corresponding to a height of an insertion slot of the receptacle 7, and the height adjustment pads 5 provide the conductive zones 2 with a pushing force toward the corresponding contact points 71 of the receptacle 7, so as to adjust a contact height of the conductive zones 2 and to achieve an effect of situating the conductive zones 2 and the corresponding contact points 71 in tight contact engagement with each other.

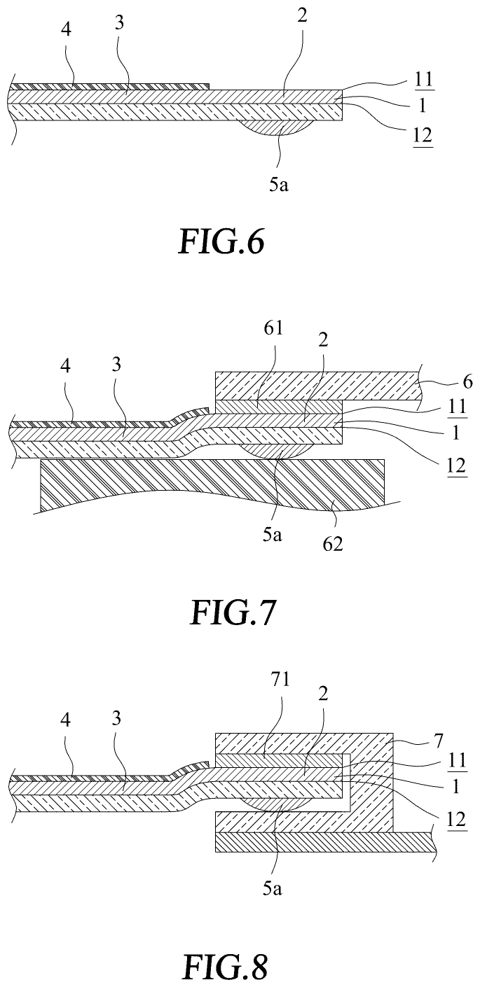

Referring to FIG. 6, which is a cross-sectional view showing height adjustment pads according to a second embodiment of the present invention being in the form of a dome-shaped conductive bump, the constituent components of the instant embodiment are generally similar to those of the first embodiment, and similar components are designated with the same reference signs for consistency, and a difference resides in that the height adjustment pads provided on the second surface 11 of the substrate 1 are each in the form of a dome-shaped height adjustment pad 5a, which similarly provides the conductive zone 2 with a pushing force toward a corresponding contact point 61 of the circuit board 6, so as to adjust a contact height of the conductive zones 2 and to achieve an effect of setting the conductive zones 2 and the corresponding contact points 61 in tight contact engagement with each other. FIG. 7 shows an example of application in which the second embodiment of the present invention is set to correspond to and contact with a circuit board 6. FIG. 8 shows an example of application in which the second embodiment of the present invention is set to correspond to and contact with a receptacle 7.

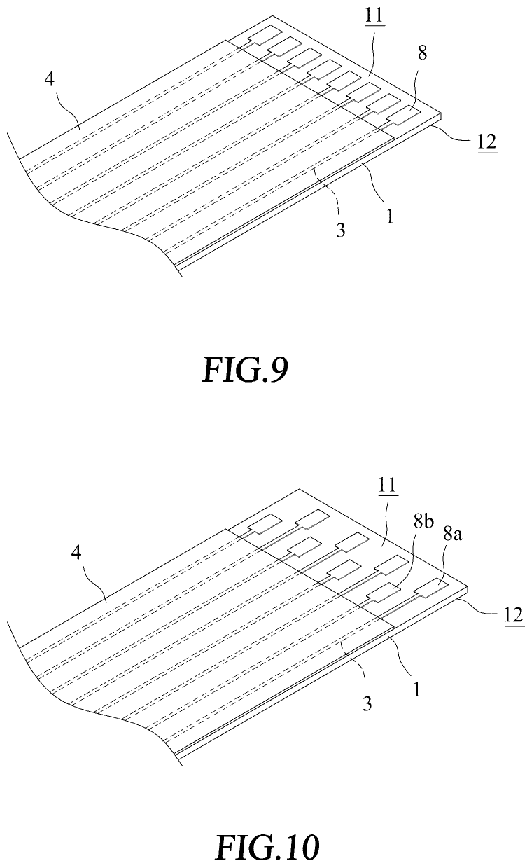

In the previously-described embodiments, the conductive zones 2 are in the form of laid conductive lines, but they can be made as conductive zones of other types. For example, FIG. 9 provides a perspective view that shows the conductive zones of the present invention can be made as contact pads 8 that are lined up in an aligned fashion. Similar to the previously described embodiments, the contact pads 8 are each arranged on the first surface 11 of the substrate 1, while the second surface 11 of the substrate 1 is provided with height adjustment pads that correspond to the contact pads 8. In this modified embodiment, when the flexible circuit board 100 is combined, at an end portion, with a circuit device (including a circuit board or a receptacle), each of the contact pads 8 in put into contact engagement with a corresponding contact point of the circuit device, and the height adjustment pads of the present invention similarly provide the contact pads 8 with a pushing force toward the corresponding contact points of the circuit device, so as to adjust a contact height of the contact pads 8 and to achieve an effect of setting the contact pads 8 and the corresponding contact points in tight contact engagement with each other.

FIG. 10 provides a perspective view showing the conductive zones of the present invention are made as two rows of contact pads arranged at front and rear sides and respectively shifted leftward and rightward. Similar to the previously described embodiments, the contact pads are each arranged on the first surface 11 of the substrate 1 and are arranged as a first row of contact pads 8a and a second row of contact pads 8b respectively set at a front side and a rear side as a front row and a rear row and respectively shifted and staggered leftward and rightward. The second surface 11 of the substrate 1 is provided with height adjustment pads corresponding to the contact pads 8a, 8b.

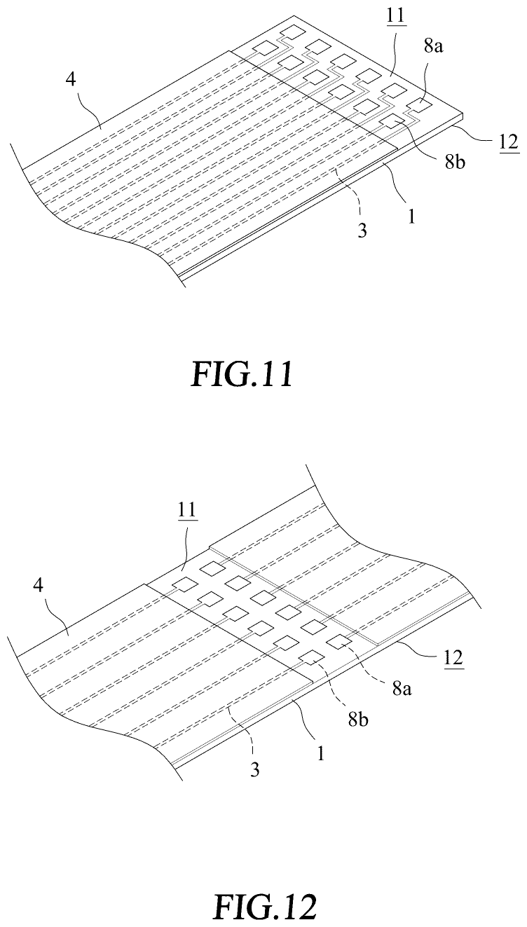

FIG. 11 provides a perspective view showing the conductive zones of the present invention are made as contact pads 8a, 8b that are arranged in a matrix form (namely arranged at front and rear sides and aligned with each other) and located at a front end position of the flexible circuit board 100. Similar to the previously described embodiments, the contact pads 8a, 8b are each arranged on the first surface 11 of the substrate 1, and the second surface 11 of the substrate 1 is provided with height adjustment pads corresponding to the contact pads 8a, 8b.

FIG. 12 provides a perspective view showing the conductive zones of the present invention are made as contact pads arranged in a matrix form and located at a middle section of the flexible circuit board 100. Similar to the previously described embodiments, the contact pads 8a, 8b are each arranged on the first surface 11 of the substrate 1, and the second surface 11 of the substrate 1 is provided with height adjustment pads corresponding to the contact pads 8a, 8b.

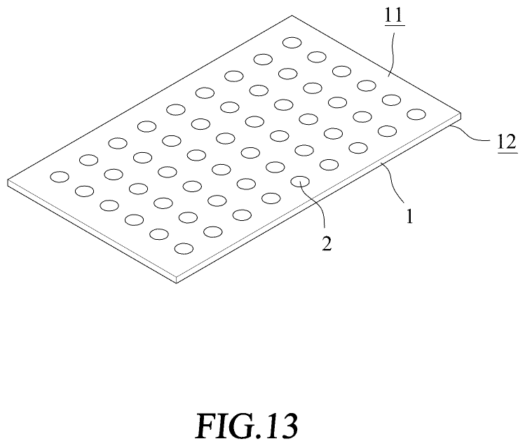

FIG. 13 provides a perspective view showing a plurality of conductive zones of a seventh embodiment of the present invention arranged in a matrix form arranged on a substrate or a circuit board. Similar to the previously described embodiments, the plurality of conductive zones 2 (or contact pads 8) are arranged in a matrix form on the first surface 11 of the substrate 1, and the second surface 11 of the substrate 1 is provided with the height adjustment pads 5 (or dome-shaped height adjustment pads 5a) respectively corresponding to the conductive zones 2 (or contact pads 8).

The embodiments described above are provided only for illustrating the present invention and are not intended to limit the scope of the present invention. Those skilled in the art may contemplate modifications and variations of the above-described embodiment based on the structural arrangement and spirit of the present invention, and such changes are considered belonging to the spirit of the present invention and the appended claims. Thus, the scope of protection should be defined solely by the appended claims.

What is claimed is:

1. A contact height adjustment structure for situating a plurality of conductive zones arranged on a first surface of a substrate of a flexible circuit board in tight contact engagement with corresponding contact points of a circuit device, comprising:
a plurality of height adjustment pads arranged on a second surface that is opposite to the first surface of the substrate of the flexible circuit board, at intervals and correspond in a one-to-one manner to the plurality of conductive zones of the circuit device; and
a pushing force being exerted to each of the plurality of conductive zones by means of the plurality of height adjustment pads through the substrate of the flexible circuit board, toward each of the corresponding contact points of the circuit device respectively.

2. The contact height adjustment structure according to claim 1, wherein each of the plurality of conductive zones comprises one of a laid conductive line, a contact pad, and a conductive bump.

3. The contact height adjustment structure according to claim 1, wherein each of the plurality of height adjustment pads comprises a plate structure or a dome-shaped bump having a predetermined height.

4. The contact height adjustment structure according to claim 1, wherein the height adjustment pads are made of one of an insulation material, a metallic material or composite materials made from the insulation material and the metallic material.

5. The contact height adjustment structure according to claim 1, wherein the plurality of conductive zones are arranged, at intervals, on the first surface of the substrate of the flexible circuit board in an aligned fashion.

6. The contact height adjustment structure according to claim 1, wherein the plurality of conductive zones are arranged, at intervals, on the first surface of the substrate of the flexible circuit board and comprise a first row of contact pads and at least one second row of contact pads that are respectively arranged at a front side and a rear side and are respectively shifted leftward and rightward.

7. The contact height adjustment structure according to claim 1, wherein the plurality of conductive zones are arranged, at intervals, in the form of a matrix on the first surface of the substrate of the flexible circuit board.

8. The contact height adjustment structure according to claim 1, wherein the corresponding circuit device comprises one of a circuit board and a receptacle.

9. The contact height adjustment structure according to claim 1, wherein the flexible circuit board comprises one of a single-sided circuit board, a double-sided circuit board, a multiple-layered circuit board, and a rigid-flex circuit board.
